(19) United States
(12) Patent Application Publication
(10) Pub. No.: US 2026/0295632 A1
(43) Pub. Date: Oct. 1, 2026

(54) THIN FILM FLATTENING MODULE AND METHOD OF FORMING THIN FILM

(71) Applicant: SAMSUNG DISPLAY CO., LTD., YONGIN-SI (KR)

(72) Inventors: Jin Won BAEK, Yongin-si (KR); Yeong Jun KIM, Yongin-si (KR); Lae Ho KIM, Yongin-si (KR); Bong Sik NOH, Yongin-si (KR); Tae Ho LEE, Yongin-si (KR); Dong Hoon HYUN, Yongin-si (KR)

(21) Appl. No.: 19/265,056

(22) Filed: Jul. 10, 2025

(30) Foreign Application Priority Data
Mar. 27, 2025 (KR) 10-2025-0039739

(51) Int. Cl. B05D 3/14; B05D 3/12

(52) U.S. Cl. CPC B05D 3/14; B05D 3/12

(57) ABSTRACT

A flattening module and a method of forming a thin film are disclosed. The flattening module includes a frame including a frame body extending from a first end in a longitudinal direction to a second end, and a mount forming an outer face of the frame body. A first electrode includes a first electrode hub adjacent to the first end of the frame body, and a plurality of first electrode segments extending from the first electrode hub in the longitudinal direction. A second electrode includes a second electrode hub adjacent to the second end of the frame body and a plurality of second electrode segments extending from the second electrode hub in the longitudinal direction. The plurality of first electrode segments and the plurality of second electrode segments are alternately arranged along a perimeter of the mount and are spaced apart from each other.

### CROSS-REFERENCE TO RELATED APPLICATION AND CLAIM OF PRIORITY

This application claims priority under 35 U.S.C. § 119 to Korean Patent Application No. 10-2025-0039739 filed on Mar. 27, 2025 in the Korean Intellectual Property Office (KIPO), the entire disclosure of which is incorporated by reference herein.

### TECHNICAL FIELD

The present disclosure relates to thin films and, more specifically, to a thin film flattening module and a method of forming a thin film using the same.

### DISCUSSION OF THE RELATED ART

In a process of applying a fluid to a substrate, such as may be done during the manufacturing of a display panel, having a uniformly flat fluid application may provide a better quality result. To flatten the fluid applied to the substrate, an electric field may be applied to the fluid.

### SUMMARY

A flattening module includes a frame having a frame body extending from a first end to a second end, in a longitudinal direction, and a mount forming an outer face of the frame body. A first electrode includes a first electrode hub adjacent to the first end of the frame body, and a plurality of first electrode segments extending from the first electrode hub in the longitudinal direction. A second electrode includes a second electrode hub adjacent to the second end of the frame body. A plurality of second electrode segments extend from the second electrode hub in the longitudinal direction. The plurality of first electrode segments and the plurality of second electrode segments are alternately arranged along a perimeter of the mount and are spaced apart from each other.

An electric potential of the first electrode and an electric potential of the second electrode may be different from each other.

The first electrode hub and the second electrode hub may be disposed on the mount.

The frame body may include a first frame body end face which extends along the longitudinal direction and forms the first end, and a second frame body end face which extends along the longitudinal direction and forms the second end. The first electrode hub may be disposed on the first frame body end face, and the second electrode hub may be disposed on the second frame body end face.

The first electrode hub may include a first electrode hub body disposed on the first frame body end face, and a plurality of first electrode hub legs. Each of the plurality of first electrode hub legs may extend from the first electrode hub body to a corresponding one of the plurality of first electrode segments. The second electrode hub may include a second electrode hub body disposed on the second frame body end face, and a plurality of second electrode hub legs, each of the plurality of second electrode hub legs extending from the second electrode hub body to a corresponding one of the plurality of second electrode segments.

The mount may have a cylindrical shape.

The mount may have a polygonal pillar shape.

The mount may include a plurality of mounting faces. A corresponding one of the plurality of first electrode segments and the plurality of second electrode segments may be mounted on each of the plurality of mounting faces. Each of a plurality of mounting edges may form a boundary between two adjacent mounting faces of the plurality of mounting faces.

The mount may include a plurality of mounting faces. A corresponding one of the plurality of first electrode segments and the plurality of second electrode segments may be mounted on each of the plurality of mounting faces. Each of a plurality of boundary faces may be disposed between two adjacent mounting faces of the plurality of mounting faces.

The frame may include a plurality of protrusions protruding from the outer face of the frame body, and a plurality of concave valleys on the outer face of the frame body.

Each of the plurality of protrusions and each of the plurality of valleys may be alternately arranged along the perimeter of the mount. Each of a plurality of mounting faces may be formed between two adjacent ones among the plurality of protrusions and the plurality of valleys. The plurality of first electrode segments and the plurality of second electrode segments may be disposed on a corresponding one of the plurality of mounting faces.

The flattening module may further include a frame driver configured to provide a rotational force to the frame.

A flattening device includes a flattening module and an electrode power supply configured to provide an electric power to the flattening module. The flattening module includes a frame having a frame body extending from a first end in a longitudinal direction to a second end, and a mount forming an outer face of the frame body. A frame driver is configured to provide a rotational force to the frame. A first electrode includes a first electrode hub adjacent to the first end of the frame body, and a plurality of first electrode segments extending from the first electrode hub in the longitudinal direction. A second electrode includes a second electrode hub adjacent to the second end of the frame body, and a plurality of second electrode segments extending from the second electrode hub in the longitudinal direction. Each of the plurality of first electrode segments and each of the plurality of second electrode segments are alternately arranged along a perimeter of the mount and are spaced apart from each other.

The flattening device may further include a mover rail system including a mover mount on which the flattening module is mounted and a mover rail, wherein the mover mount is movably coupled to the mover rail.

The flattening device may further include a sensor configured to measure a thickness of a display module disposed below the flattening module, and a controller electrically connected to the sensor, the electrode power supply, and the flattening module.

The flattening module may include a front flattening module and a rear flattening module which are spaced apart from each other and configured to move forward. The sensor may be disposed between the front flattening module and the rear flattening module, and the controller may control the rear flattening module based on information on the thickness of the display module which is acquired from the sensor.

A method of forming a thin film includes moving a fluid application unit forward and applying a film layer to an upper face of a substrate. A flattening module forms an electric flux above the film layer and moves forward while rotating and flattening the film layer.

The flattening module may include a frame having a frame body extending from a first end in a longitudinal direction to a second end, and a mount forming an outer face of the frame body. A first electrode may include a first electrode hub adjacent to the first end of the frame body, and a plurality of first electrode segments extending from the first electrode hub in the longitudinal direction. A second electrode may include a second electrode hub adjacent to the second end of the frame body, and a plurality of second electrode segments may extend from the second electrode hub in the longitudinal direction. Each of the plurality of first electrode segments and each of the plurality of second electrode segments may be alternately arranged along a perimeter of the mount and may be spaced apart from each other.

An operation of the flattening module may include rotating a front flattening module and moving the front flattening module forward while the front flattening module forms an electric flux. A thickness of the film layer may be measured at a point of the film layer by using a sensor. The measured thickness may be compared with a reference thickness by a controller. An electric flux may be formed above the point of the film layer by a rear flattening module disposed behind the front flattening module and moving the rear flattening module forward while the rear flattening module rotates, when the measured thickness is greater than or equal to the reference thickness.

The sensor may change a measurement position of the film layer and may measure a thickness of the film layer, when the measured thickness is less than the reference thickness.

### BRIEF DESCRIPTION OF THE DRAWINGS

The accompanying drawings, which are included to provide a further understanding of the disclosure and are incorporated in and constitute a part of the disclosure, illustrate embodiments of the disclosure and together with the description serve to explain the principle of the disclosure.

FIG. 1 is a perspective view illustrating that a film layer is applied to a substrate.

FIG. 2 is a perspective view of a flattening module according to an embodiment of the disclosure.

FIG. 3 is a side view illustrating a frame of a flattening module according to an embodiment of the disclosure.

FIG. 4 is a perspective view illustrating a first electrode of an electrode assembly according to an embodiment of the disclosure.

FIG. 5 is a perspective view illustrating a second electrode of an electrode assembly according to an embodiment of the disclosure.

FIG. 6 is a perspective view illustrating a first electrode illustrated in FIG. 4 and a second electrode illustrated in FIG. 5, coupled to a frame illustrated in FIG. 2.

FIG. 7 is an exploded cross-sectional view illustrating a flattening module illustrated in FIG. 6.

FIG. 8 is an exploded cross-sectional view illustrating that a spacer as a flattening module illustrated in FIG. 7 is formed on a mount.

FIG. 9 is a perspective view illustrating a polygonal prism-shaped frame.

FIG. 10 is a perspective view illustrating a frame with a boundary face.

FIG. 11 is a perspective view illustrating that an electrode assembly is coupled to a frame illustrated in FIG. 9 to form a flattening module.

FIG. 12 is a cross-sectional view illustrating a frame in which a mounting face forms a mounting edge and a mounting trench.

FIG. 13 is a cross-sectional view illustrating that an electrode assembly is coupled to a frame illustrated in FIG. 12.

FIG. 14 is a perspective view illustrating a flattening module including an electrode hub body and an electrode hub leg.

FIG. 15 is a perspective view illustrating a mover rail system.

FIG. 16 is a block diagram illustrating a flattening device according to an embodiment of the disclosure.

FIG. 17 is a cross-sectional view illustrating a flattening module disposed on a display panel.

FIG. 18 is a cross-sectional view illustrating a plurality of flattening modules disposed on a display panel.

FIG. 19 is a flowchart illustrating a method of forming a thin film according to an embodiment of the disclosure.

FIG. 20 is a flowchart illustrating a flattening module operation step illustrated in FIG. 19.

### DETAILED DESCRIPTION OF THE EMBODIMENTS

In an embodiment of the disclosure, the XYZ coordinate system used may be a Cartesian coordinate system. For example, a positive Z-axis direction may indicate an upward direction, and a negative Z-axis direction may indicate a downward direction.

For example, a positive X-axis direction may indicate a forward direction, and a negative X-axis direction may indicate a rearward direction. For example, a positive Y-axis direction may indicate a right direction, and a negative Y-axis direction may indicate a left direction.

Embodiments of the present disclosure relate to a novel thin film flattening module and method for improving the uniformity of fluid-applied films, such as monomer layers, on substrates like glass in display panel manufacturing. This technology addresses the common challenge of uneven thickness in liquid film layers that are applied to a substrate prior to curing or solidification. Variations in thickness can degrade display quality, and embodiments of the present disclosure provide a mechanism for flattening such films using a spatially and temporally varying electric field.

This may be accomplished using a flattening module featuring a cylindrical or polygonal frame with a mounting portion that supports a complex electrode assembly. This assembly comprises a first and second electrode, each with a respective hub at opposite ends of the frame, and multiple electrode segments that extend longitudinally along the outer surface of the frame. These electrode segments are arranged in an alternating, azimuthal pattern, thereby forming an electric field pattern that varies around the circumference of the frame. When different electric potentials are applied to the first and second electrodes, a time-varying electric field is generated between them, particularly at specific structural features like mounting edges or boundary faces on the frame. This field influences charged or polarizable components in the fluid layer, redistributing the material to achieve a more uniform film thickness.

To enhance the field's effectiveness, the frame can rotate, allowing the electric flux to dynamically interact with the fluid layer. The module can be mounted on a mover module that traverses along a substrate, so the flattening operation covers the entire film surface. A sensor measures film thickness at various points in real time, and a controller adjusts the operation of one or more flattening modules accordingly.

In some embodiments, there are both front and rear flattening modules: the front module performs the initial flattening, while the rear module is dynamically adjusted based on sensor feedback to refine any remaining uneven areas.

The method associated with this device includes steps for applying the film layer, operating the rotating and translating flattening module, and using sensor-based feedback to optimize film uniformity. The process ensures that areas of the film that are too thick are selectively flattened, producing a consistent and high-quality thin film suitable for encapsulation in displays.

Overall, embodiments of the present disclosure integrate mechanical motion, electrical field manipulation, and feedback control into a single system capable of delivering precision thin film flattening, which is useful for the next generation of high-performance display technologies.

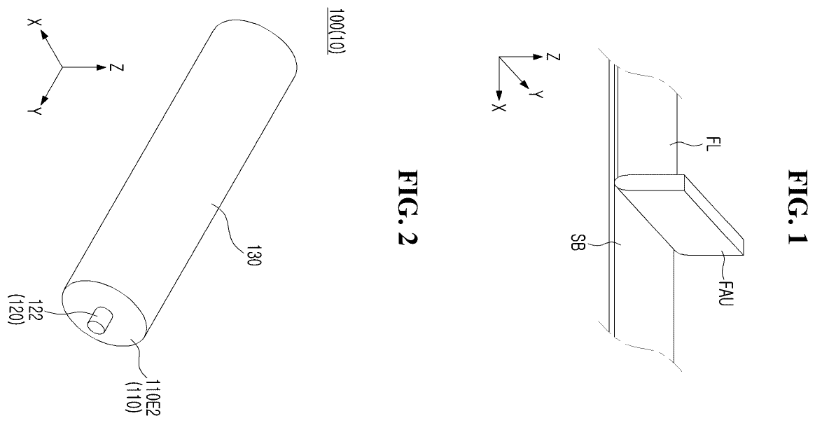

FIG. 1 illustrates that a film layer is applied to a substrate.

Referring to FIG. 1, a display panel (SB, FL) may be used to display an image. The display panel (SB, FL) may include a substrate SB. For example, the substrate SB may include a glass material.

For example, the substrate SB may have a shape of a plate or a board. For example, the substrate SB may have an upper face and a lower face. For example, the substrate SB may extend rearward from a front end and lead to a rear end.

The display panel (SB, FL) may include a film layer FL. The film layer FL may include a monomer. The film layer FL may be stacked on the substrate SB. For example, the film layer FL may be applied to the upper face of the substrate SB.

For example, a fluid application unit FAU may apply the film layer FL of a fluid state to the substrate SB. For example, the fluid application unit FAU may apply a film layer FL wrapping the substrate SB to the substrate SB in a thin film encapsulation process.

For example, the fluid application unit FAU may apply the film layer FL of the fluid state to the substrate SB while moving in a longitudinal direction of the substrate SB. For another example, while the substrate SB moves in the longitudinal direction, the fluid application unit FAU may apply the film layer FL of the fluid state to the substrate SB.

The film layer FL applied to the substrate SB may be solidified (e.g., converted into a solid state) over time. A thickness of the film layer FL applied to the substrate SB may be measured with reference to a direction in which the film layer FL is stacked on the substrate SB.

The thickness of the film layer FL applied to the substrate SB may vary depending on a horizontal position of the film layer FL. For example, the thickness of the film layer FL applied to the substrate SB may vary depending on a longitudinal position of the substrate SB. A flattening module 10 (see FIGS. 2 to 15) according to an embodiment of the disclosure may flatten the film layer FL.

Thus, a film layer composed of a fluid monomer is applied to the upper surface of a substrate by a fluid application unit moving along the substrate's length, and since the resulting layer may vary in thickness depending on position, a flattening module is used to achieve uniformity.

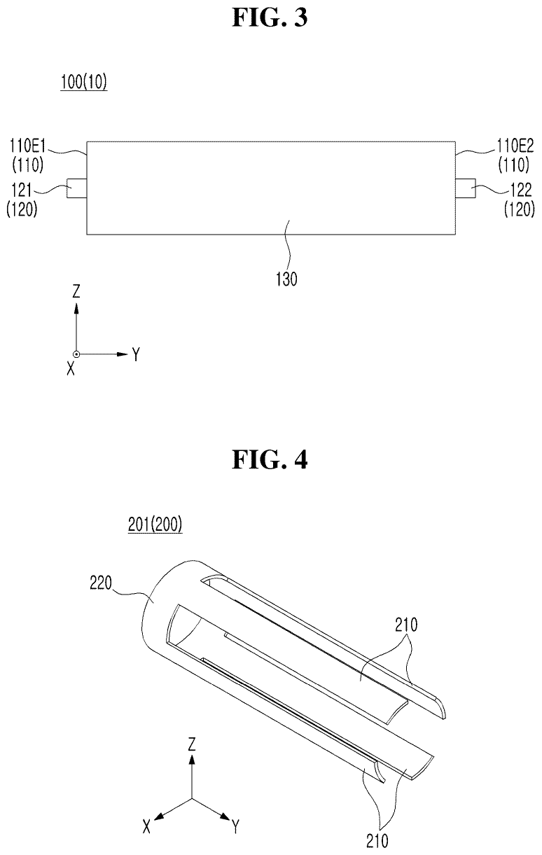

FIGS. 2 and 3 illustrate a frame of a flattening module according to an embodiment of the disclosure when viewed from different directions.

Referring to FIGS. 2 and 3, the flattening module 10, according to an embodiment of the disclosure, may include a frame 100. The frame 100 may include a frame body 110.

The frame body 110 may have a pillar shape. For example, the frame body 110 may have a cylindrical shape. For example, an outer face of the frame body 110 may have a cylindrical shape.

For example, the frame body 110 may extend from a first end of the frame body 110 and lead to a second end of the frame body 110. A direction in which the frame body 110 extends may be a longitudinal direction of the frame body 110.

For example, a first frame body end face 110E1 may be a face formed at the first end of the frame body 110. For example, a second frame body end face 110E2 may be a face formed at the second end of the frame body 110.

The first frame body end face 110E1 and the second frame body end face 110E2 may be directed toward the longitudinal direction of the frame body 110. A direction in which the first frame body end face 110E1 faces may be opposite to a direction in which the second frame body end face 110E2 faces.

The frame 100 may include a frame shaft 120. The frame shaft 120 may be a rotational axis of the frame body 110. For example, the frame body 110 may rotate with the frame shaft 120 as the rotational axis.

A plurality of frame shafts 120 may be provided. For example, the frame 100 may include a first frame shaft 121 and a second frame shaft 122. The frame shaft 120 may include or indicate at least one of the first frame shaft 121 or the second frame shaft 122.

The frame shaft 120 may be connected to, coupled to, or formed on the frame body 110.

For example, the first frame shaft 121 may be connected to, coupled to, or formed at the first end of the frame body 110. For example, the first frame shaft 121 may protrude from the first frame body end face 110E1.

For example, the second frame shaft 122 may be connected to, coupled to, or formed at the second end of the frame body 110. For example, the second frame shaft 122 may protrude from the second frame body end face 110E2.

For example, the frame shaft 120 and the frame body 110 may be formed integrally as a single continuous structure. For example, the frame shaft 120 may extend or protrude from the frame body 110.

For example, the frame shaft 120 may protrude from the frame body 110 in the longitudinal direction of the frame body 110. For example, the longitudinal direction of the frame body 110 may be an “axial direction” of the frame 100.

For example, the first frame shaft 121 may protrude from the first end of the frame body 110. For example, the second frame shaft 122 may protrude from the second end of the frame body 110.

The frame 100 may include a mount 130. The mount 130 may be a portion of the outer face of the frame body 110. For example, the mount 130 may extend in the longitudinal direction of the frame body 110.

Thus, the flattening module includes a cylindrical, pillar-shaped frame with a longitudinal axis and integrated rotating shafts at both ends, as well as a mounting portion on its outer surface for supporting additional components.

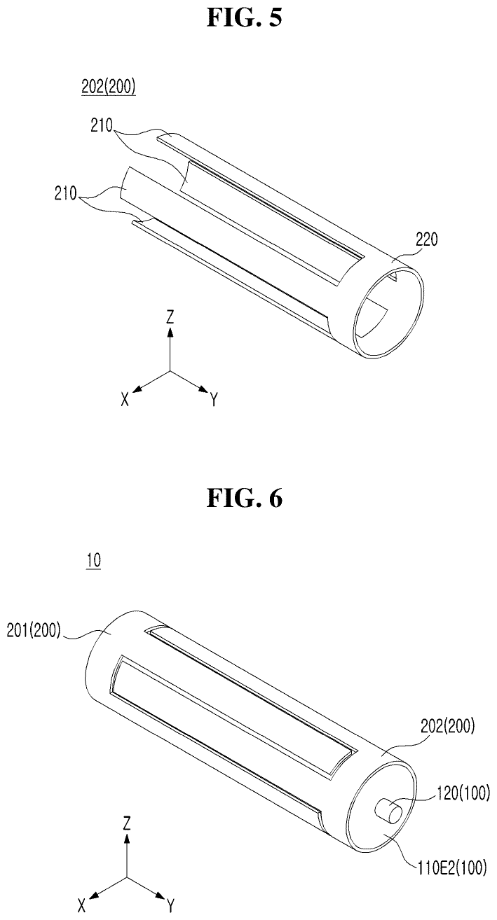

FIG. 4 illustrates a first electrode of an electrode assembly according to an embodiment of the disclosure. FIG. 5 illustrates a second electrode of an electrode assembly according to an embodiment of the disclosure. FIG. 6 illustrates that a first electrode illustrated in FIG. 4 and a second electrode illustrated in FIG. 5 are coupled to a frame illustrated in FIG. 2.

Referring to FIGS. 4 to 6, the flattening module 10 may include an electrode assembly 200. The electrode assembly 200 may be coupled to the frame 100. For example, at least a portion of the electrode assembly 200 may be coupled or connected to the mount 130.

The electrode assembly 200 may include or indicate at least one of a first electrode 201 or a second electrode 202. The electrode assembly 200 may include an electrode segment 210.

The electrode segment 210 may extend in the longitudinal direction of the frame 100 (see FIG. 2). For example, a longitudinal direction of the electrode segment 210 may be a direction in which the electrode segment 210 extends.

A plurality of electrode segments 210 may be provided. For example, the electrode assembly 200 may include a plurality of electrode segments 210. The plurality of electrode segments 210 may be spaced apart from each other.

For example, the plurality of electrode segments 210 may be sequentially arranged in an azimuthal direction. The azimuthal direction may be set with reference to the rotational axis of the frame 100 (see FIG. 2). For example, the azimuthal direction may be a circumferential direction of the mount 130 (see FIG. 2).

The electrode assembly 200 may include an electrode hub 220. The electrode hub 220 may be adjacent to an end of the frame 100 (see FIG. 2). For example, the electrode hub 220 of the first electrode 201 may be adjacent to the first end of the frame 100 (see FIG. 2). For example, the electrode hub 220 of the second electrode 202 may be adjacent to the second end of the frame 100 (see FIG. 2). As used herein, the term “adjacent” may mean that the two elements are proximate to one another, that they may touch one another, or where there are a number of similar elements all arranged in a row, elements are adjacent to one another if there are no intervening similar elements disposed therebetween.

The electrode hub 220 may be connected to the electrode segment 210. For example, the electrode segment 210 may extend from the electrode hub 220. For example, the electrode segment 210 of the first electrode 201 may extend from the electrode hub 220 of the first electrode 201. For example, the electrode segment 210 of the second electrode 202 may extend from the electrode hub 220 of the second electrode 202.

The electrode segment 210 of the first electrode 201 may be referred to as a “first electrode segment.” The electrode segment 210 of the second electrode 202 may be referred to as a “second electrode segment.” The electrode hub 220 of the first electrode 201 may be referred to as a “first electrode hub.” The electrode hub 220 of the second electrode 202 may be referred to as a “second electrode hub.”

Thus, the flattening module includes an electrode assembly comprising first and second electrodes, each with multiple electrode segments extending longitudinally from respective hubs at opposite ends of the frame, with the segments arranged in an azimuthal pattern around the mounting portion.

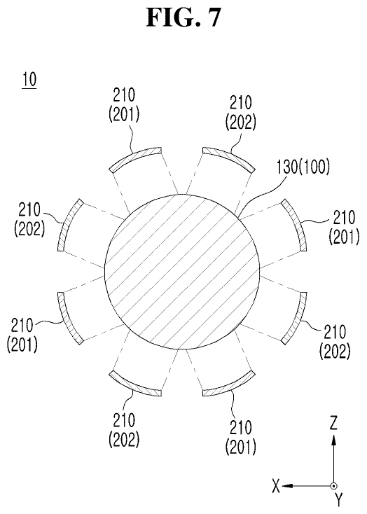

FIG. 7 illustrates, as an exploded view, a cross section of a flattening module illustrated in FIG. 6.

Referring to FIGS. 6 and 7, the first electrode 201 and the second electrode 202 may be spaced apart from each other. For example, the first electrode 201 and the second electrode 202 may be electrically separated.

For example, if different electric potentials are applied to the first electrode 201 and the second electrode 202, an electric field may be formed between the first electrode 201 and the second electrode 202.

For example, the plurality of electrode segments 210 of the first electrode 201 and the plurality of electrode segments 210 of the second electrode 202 may be alternately arranged in the azimuthal direction.

For example, the electrode segment 210 of the first electrode 201 and the electrode segment 210 of the second electrode 202 may be spaced apart in the azimuthal direction. For example, an electric field in the azimuthal direction may be formed between the electrode segment 210 of the first electrode 201 and the electrode segment 210 of the second electrode 202.

Thus, the first and second electrodes of the flattening module are electrically separated and have alternately arranged electrode segments in the azimuthal direction, enabling the formation of an electric field between them when different potentials are applied.

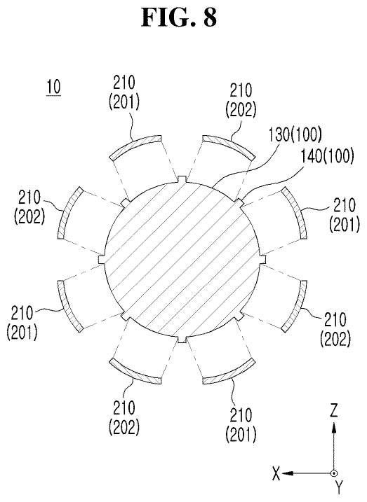

FIG. 8 illustrates that a spacer as a flattening module illustrated in FIG. 7 is formed on a mount.

Referring to FIG. 8, the frame 100 may include a spacer 140. For example, the spacer 140 may be formed on the mount 130. For example, the spacer 140 may protrude from the mount 130.

The spacer 140 may be connected or coupled to the frame body 110 (see FIG. 2). For example, the spacer 140 may be formed integrally with the frame body 110 (see FIG. 2) as a single continuous structure.

The spacer 140 may extend, for example, in the longitudinal direction of the frame body 110 (see FIG. 2). A longitudinal direction of the spacer 140 may be a direction in which the spacer 140 extends.

A plurality of spacers 140 may be provided. For example, the frame 100 may include a plurality of spacers 140. The plurality of spacers 140 may be sequentially arranged in the azimuthal direction. For example, the plurality of spacers 140 and the plurality of electrode segments 210 (see FIGS. 4 and 5) may be alternately arranged in the azimuthal direction.

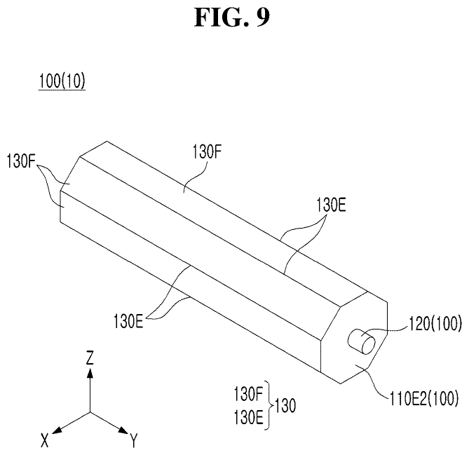

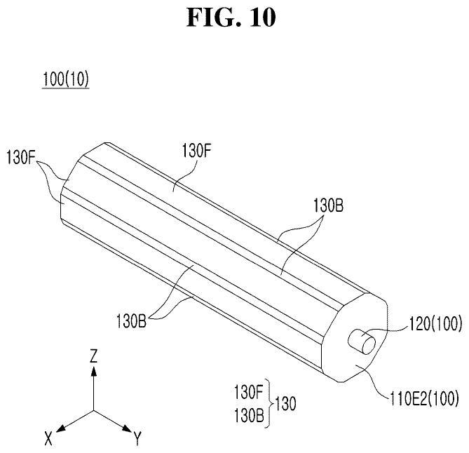

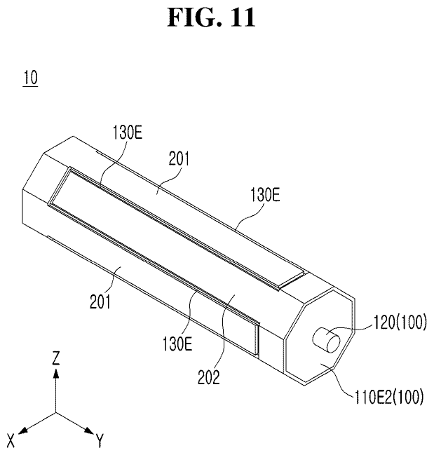

FIG. 9 illustrates a polygonal pillar-shaped frame. FIG. 10 illustrates a frame with a boundary face. FIG. 11 illustrates that an electrode assembly is coupled to a frame illustrated in FIG. 9 to form a flattening module.

Referring to FIG. 9, a shape of the frame body 110 may be, for example, a polygonal pillar shape. For example, the shape of the frame body 110 may be an octagonal pillar shape. For example, a shape of the mount 130 may be a polygonal pillar shape. For example, the shape of the mount 130 may be an octagonal pillar shape.

The mount 130 may include a mounting face 130F. The electrode segment 210 (see FIGS. 4 and 5) may be mounted, coupled, or connected to the mounting face 130F.

The mounting face 130F may be a portion of the outer face of the frame body 110. The mounting face 130F may form a plane. The mounting face 130F may be divided into a plurality of parts. For example, the plurality of mounting faces 130F may be sequentially arranged in the azimuthal direction.

The mount 130 may include a mounting edge 130E. The mounting edge 130E may form a boundary between two adjacent mounting faces 130F. For example, the plurality of mounting faces 130F and the plurality of mounting edges 130E may be alternately arranged in the azimuthal direction.

Referring to FIG. 10, a boundary face 130B may be formed between two adjacent mounting faces 130F among the plurality of mounting faces 130F. A plurality of boundary faces 130B may be provided. For example, the plurality of mounting faces 130F and the plurality of boundary faces 130B may be alternately arranged in the azimuthal direction.

Referring to FIGS. 9 to 11, if different electric potentials are applied to the first electrode 201 and the second electrode 202, an electric field may be formed between the first electrode 201 and the second electrode 202.

For example, if different electric potentials are applied to the first electrode 201 and the second electrode 202, an electric field may be formed at the mounting edge 130E or at the boundary face 130B.

Thus, the frame may include multiple spacers protruding from the mounting portion and arranged alternately with electrode segments in the azimuthal direction, and when different electric potentials are applied to the first and second electrodes mounted on polygonal faces, electric fields may form at the mounting edges or boundary faces between adjacent electrode segments.

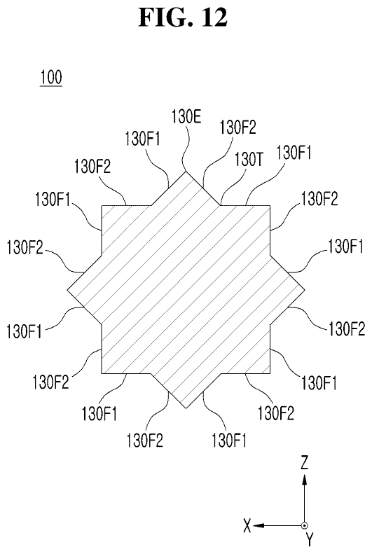

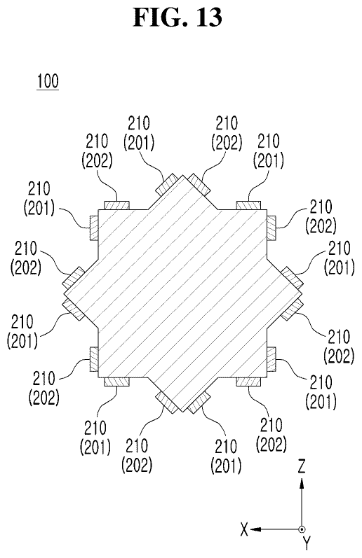

FIG. 12 illustrates a cross section of a frame in which a mounting face forms a mounting edge and a mounting trench. FIG. 13 is a cross-sectional view illustrating that an electrode assembly is coupled to a frame illustrated in FIG. 12.

Referring to FIG. 12 and FIG. 13, mounting faces 130F1 and 130F2 may include or indicate at least one of a first mounting face 130F1 or a second mounting face 130F2. For example, a plurality of first mounting faces 130F1 and a plurality of second mounting faces 130F2 may be alternately arranged in the azimuthal direction.

The mounting faces 130F1 and 130F2 may form a mounting edge 130E and a mounting trench 130T. For example, a plurality of mounting edges 130E and a plurality of mounting trenches 130T may be alternately arranged in the azimuthal direction. For example, the mounting faces 130F1 and 130F2 may be disposed between the mounting edges 130E and the mounting trenches 130T adjacent to each other.

For example, the mounting edge 130E may be an area, in which the first mounting face 130F1 and the second mounting face 130F2 adjacent to each other meet, to form a protrusion.

For example, the mounting trench 130T may be an area, in which the second mounting face 130F2 and the first mounting face 130F1 adjacent to each other meet, to form a concave portion or a valley.

The electrode segment 210 may be disposed or mounted on the mounting faces 130F1 and 130F2. The electrode segment 210 of the first electrode 201 and the electrode segment 210 of the second electrode 202 may be spaced apart from each other.

For example, the electrode segment 210 of the first electrode 201 may be disposed or mounted on the first mounting face 130F1, and the electrode segment 210 of the second electrode 202 may be disposed or mounted on the second mounting face 130F2.

The electrode segment 210 disposed or mounted on the mounting faces 130F1 and 130F2 may have a plate shape or a strap shape. For another example, the electrode segment 210 disposed or mounted on the mounting faces 130F1 and 130F2 may have a wire shape.

If different electric potentials are applied to the first electrode 201 and the second electrode 202, an electric flux may be formed at the mounting edge 130E. The electric flux formed at the mounting edge 130E may meet the film layer FL (see FIG. 1).

Thus, the frame includes alternating first and second mounting faces that form protruding edges and recessed trenches in the azimuthal direction, with electrode segments mounted on these faces such that, when different electric potentials are applied to the first and second electrodes, an electric flux is generated at the mounting edges to interact with the film layer.

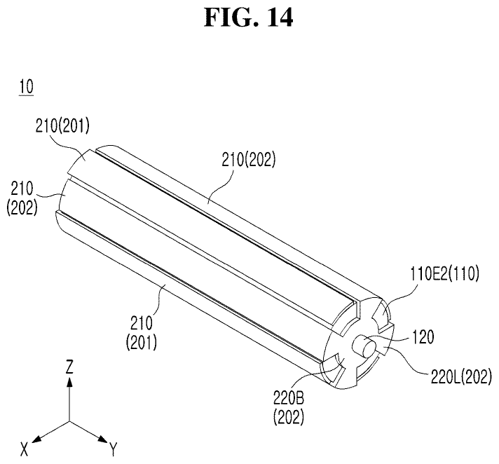

FIG. 14 illustrates a flattening module including an electrode hub body and an electrode hub leg.

Referring to FIGS. 2 to 5 and FIG. 14, the electrode hub 220 and the frame body 110 may be arranged in the longitudinal direction of the frame body 110. For example, the electrode hub 220 of the first electrode 201, the frame body 110, and the electrode hub 220 of the second electrode 202 may be sequentially arranged in the longitudinal direction of the frame body 110.

The electrode hub 220 may include an electrode hub body 220B and an electrode hub leg 220L. The electrode hub body 220B may be disposed or coupled to an end of the frame body 110.

For example, the electrode hub body 220B of the first electrode 201 may be disposed or coupled to the first frame body end face 110E1 (see FIG. 3). For example, the electrode hub body 220B of the second electrode 202 may be disposed or coupled to the second frame body end face 110E2.

The electrode hub leg 220L may be connected to the electrode hub body 220B. For example, the electrode hub leg 220L may extend in a radial direction from the electrode hub body 220B. For example, the electrode hub leg 220L may extend from the electrode hub body 220B and lead to the electrode segment 210.

A plurality of electrode hub legs 220L may be provided. For example, the plurality of electrode hub legs 220L may be spaced apart in the azimuthal direction.

Each of the plurality of electrode hub legs 220L may be connected to a corresponding one of the plurality of electrode segments 210.

For example, each of the plurality of electrode hub legs 220L of the first electrode 201 may be connected to a corresponding one of the plurality of electrode segments 210 of the first electrode 201.

For example, each of the plurality of electrode hub legs 220L of the second electrode 202 may be connected to a corresponding one of the plurality of electrode segments 210 of the second electrode 202.

The electrode hub body 220B of the first electrode 201 may be referred to as a “first electrode hub body.” The electrode hub body 220B of the second electrode 202 may be referred to as a “second electrode hub body.”

The electrode hub leg 220L of the first electrode 201 may be referred to as a “first electrode hub leg.” The electrode hub leg 220L of the second electrode 202 may be referred to as a “second electrode hub leg.”

Referring to FIGS. 2 to 14, electric conductivity of the electrode assembly 200 may be higher than electric conductivity of the frame 100.

For example, the electrode assembly 200 may be formed of a material including at least one of a conductive polymer, a carbon nano-tube, or a metal. For example, the frame 100 may be formed of a material including at least one of a polymer or a ceramic.

Thus, the electrode hubs of the first and second electrodes are positioned at opposite ends of the frame and each include a hub body and multiple radially extending hub legs that connect to corresponding electrode segments, with the electrode assembly made of a more conductive material than the frame.

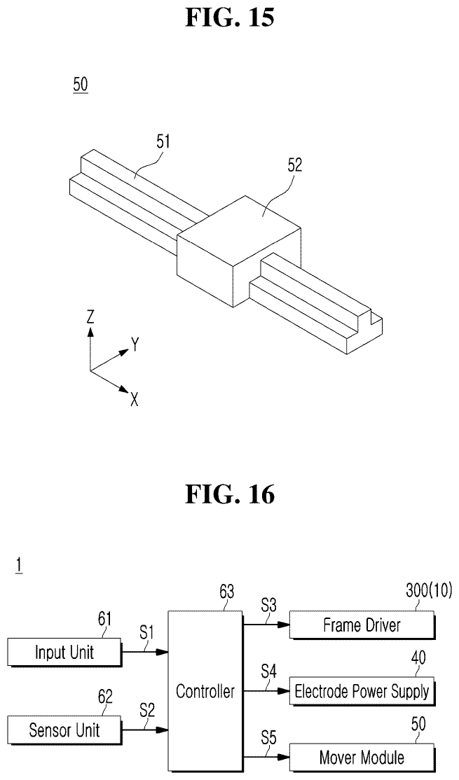

FIG. 15 illustrates a mover rail system.

Referring to FIG. 15, a mover rail system 50 may include a mover rail 51. The mover rail 51 may have a shape of a rail. The mover rail 51 may have a shape extending in one direction.

For example, the extending direction of the mover rail 51 may be a longitudinal direction of the mover rail 51. For example, the longitudinal direction of the mover rail 51 may be the longitudinal direction of the substrate SB (see FIG. 1).

The mover rail system 50 may include a mover mount 52. The mover mount 52 may be movably coupled to the mover rail 51. For example, the mover mount 52 may move along the mover rail 51. For example, the mover rail system 50 may separately include an element that drives the mover mount 52.

The flattening module 10 (see FIGS. 2 to 14) may be connected, coupled, or mounted to the mover mount 52. For example, a position of the flattening module 10 (see FIGS. 2 to 12) may depend on a position of the mover mount 52.

FIG. 16 is a block diagram illustrating a flattening device according to an embodiment of the disclosure.

Referring to FIGS. 1 to 16, a flattening device 1 may include an input unit 61. The input unit 61 may obtain an input from a user, etc.

The input unit 61 may generate a first signal S1. The first signal S1 may include information on the input obtained by the input unit 61. For example, the first signal S1 may include command information about an operation of the flattening device 1.

The flattening device 1 may include a sensor 62. The sensor 62 may include at least one of an infrared sensor, an ultrasonic sensor, a laser sensor, or a visible light sensor.

For example, the sensor 62 may measure a thickness of the film layer FL. The sensor 62 may generate a second signal S2. For example, the second signal S2 may include information on a value measured by the sensor 62.

The flattening device 1 may include a controller 63. The controller 63 may perform a calculation. For example, the controller 63 may be implemented through at least one of a processor, a central processing unit (CPU), a graphical processing unit (GPU), an electric circuit, a circuit board, or a computer.

The controller 63 may process a signal. The controller 63 may transmit and receive a signal. For example, the controller 63 may generate output signals S3, S4, and S5 based on the input signals S1 and S2.

The input signals S1 and S2 may include at least one of the first signal S1 or the second signal S2. The output signals S3, S4, and S5 may include at least one of a third signal S3, a fourth signal S4, or a fifth signal S5.

The flattening module 10 may include a frame driver 300. For example, the frame driver 300 may include an electric motor. The frame driver 300 may be mounted, coupled, or fixed to, for example, the mover mount 52.

The frame driver 300 may be coupled to the frame 100. For example, the frame driver 300 may be coupled to the frame shaft 120. The frame driver 300 may provide a rotational force to the frame 100. For example, the frame 100 may rotate by the frame driver 300.

The controller 63 may control the frame driver 300. For example, the controller 63 may transmit the third signal S3 to the frame driver 300. The frame driver 300 may operate in response to the third signal S3. For example, the third signal S3 may include command information about at least one of a rotational direction or a rotational speed of the frame 100.

The flattening device 1 may include an electrode power supply 40. The electrode power supply 40 may be electrically connected to the first electrode 201 and the second electrode 202.

For example, an electric potential difference between the first electrode 201 and the second electrode 202 may be formed by the electrode power supply 40. For example, the electrode power supply 40 may apply different electric potentials to the first electrode 201 and the second electrode 202.

For example, an electric potential of the first electrode 201 may be constant over time, and an electric potential of the second electrode 202 may be constant over time.

For example, the electric potential of the first electrode 201 may vary over time, and the electric potential of the second electrode 202 may vary over time. However, the electric potential difference between the first electrode 201 and the second electrode 202 may be constant over time.

For example, a magnitude of the electric potential of the first electrode 201 and a magnitude of the electric potential of the second electrode 202 may be the same, and a difference between a phase of the electric potential of the first electrode 201 and a phase of the electric potential of the second electrode 202 may be 180 degrees.

The controller 63 may control the electrode power supply 40. For example, the controller 63 may transmit the fourth signal S4 to the electrode power supply 40. The electrode power supply 40 may operate in response to the fourth signal S4. The fourth signal S4 may include information on an electric potential of the electrode assembly 200.

The controller 63 may control the mover rail system 50. For example, the controller 63 may transmit the fifth signal S5 to the mover rail system 50. The fifth signal S5 may include information on the position of the flattening module 10 with respect to the substrate SB. For example, the fifth signal S5 may include information on the position of the mover mount 52 with respect to the mover rail 51.

The mover rail system 50 may operate in response to the fifth signal S5. For example, the mover rail system 50 may adjust the position of the mover mount 52 in response to the fifth signal S5.

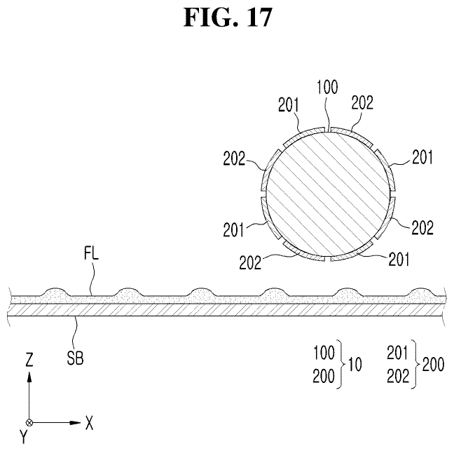

FIG. 17 illustrates a cross section of a flattening module disposed on a display panel.

Referring to FIG. 17, the flattening module 10 may be disposed above the film layer FL. For example, the film layer FL may be disposed between the substrate SB and the flattening module 10. For example, a lower face of the film layer FL may face and contact the substrate SB, and an upper face of the film layer FL may face the flattening module 10.

Referring to FIGS. 1 to 17, the film layer FL stacked on the substrate SB may form different thicknesses depending on a point of the substrate SB. An electric field may be formed between the electrode segment 210 of the first electrode 201 and the electrode segment 210 of the second electrode 202.

For example, an electric flux formed by the flattening module 10 may meet the film layer FL. For example, the film layer FL may be affected by the electric field formed by the flattening module 10.

For example, electric charges included in the film layer FL or an electric dipole formed in the film layer FL may receive a force from the electric flux formed by the flattening module 10.

For example, the degree of an influence that the film layer FL receives from the electric field may vary depending on the thickness of the film layer FL. For example, an influence that the film layer FL receives from the electric field at a point where the thickness of the film layer FL is relatively thick may be greater than an influence that the film layer FL receives from the electric field at a point where the thickness of the film layer FL is relatively thin.

For example, the film layer FL at a point where the thickness of the film layer FL is relatively thick may move toward a point where the thickness of the film layer FL is relatively thin. Through this process, the film layer FL may be flattened.

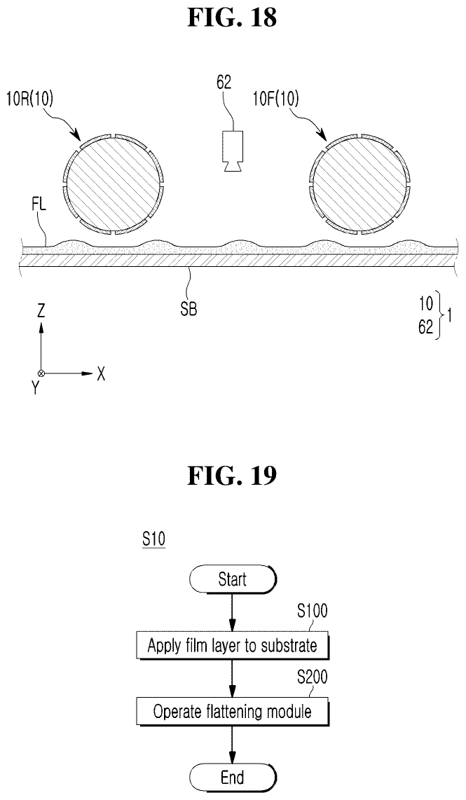

FIG. 18 illustrates a cross section of a plurality of flattening modules disposed on a display panel.

Referring to FIG. 18, the flattening device 1 may include a plurality of flattening modules 10. For example, the flattening device 1 may include a front flattening module 10F and a rear flattening module 10R.

For example, the front flattening module 10F and the rear flattening module 10R may be disposed above the film layer FL. The front flattening module 10F may be disposed in front of the rear flattening module 10R.

The sensor 62 may be disposed between the front flattening module 10F and the rear flattening module 10R. For example, relative positions of the front flattening module 10F, the rear flattening module 10R, and the sensor 62 may be the same over time.

The front flattening module 10F, the rear flattening module 10R, and the sensor 62 may move simultaneously. For example, the front flattening module 10F, the rear flattening module 10R, and the sensor 62 may move forward simultaneously.

The sensor 62 may be disposed behind the front flattening module 10F. The sensor 62 may measure a thickness of a portion of the film layer FL that is flattened by the front flattening module 10F.

The controller 63 (see FIG. 16) may control the rear flattening module 10R in response to the second signal S2. For example, the rear flattening module 10R may apply an electric field to a portion of the film layer FL that is not flattened.

Referring to FIGS. 1 to 18, as different electric potentials are applied to the first electrode 201 and the second electrode 202, the flattening module 10 may form an electric flux (or electric field).

For example, an electric flux may be formed between the electrode segment 210 of the first electrode 201 and the electrode segment 210 of the second electrode 202. For example, an electric flux may be formed at the plurality of mounting edges 130E, the plurality of boundary faces 130B, and the plurality of spacers 140.

The electric flux formed by the flattening module 10 may meet the film layer FL in the azimuthal direction with reference to the longitudinal direction of the frame body 110.

The “azimuthal direction” may be set with reference to the longitudinal direction of the frame body 110. If the frame driver 300 operates, the frame body 110 may rotate in the azimuthal direction.

For example, if the frame body 110 rotates in the azimuthal direction, the electric flux (or electric field) formed by the frame module 10 may rotate in the azimuthal direction.

For example, if the frame body 110 rotates in the azimuthal direction, an electric flux (or magnetic field) formed between the frame 100 and the film layer FL may vary over time.

If the electric potential difference between the first electrode 201 and the second electrode 202 varies over time, the electric flux (or magnetic field) formed between the frame 100 and the film layer FL may vary over time. For example, the voltage provided by the electrode power supply 40 to the electrode assembly 200 may include an alternating current (AC) voltage.

For example, if the frame body 110 rotates in the azimuthal direction or the electric potential difference between the first electrode 201 and the second electrode 202 varies over time, the electric flux applied to the film layer FL may vary over time.

As the electric flux applied to the film layer FL varies over time, the phenomenon in which the electric flux is concentrated on a portion of the film layer FL can be suppressed. As a result, the film layer FL can be effectively flattened.

FIG. 19 is a flowchart illustrating a method of forming a thin film according to an embodiment of the disclosure.

Referring to FIGS. 1 to 19, a thin film forming method S10 may include a step S100 of applying the film layer FL to the substrate SB. For example, the fluid application unit FAU may apply the film layer FL to the substrate SB. The film layer FL may form a thin film.

The thin film forming method S10 may include a step S200 of operating the flattening module 10. For example, the controller 63 may control the electrode power supply 40 so that an electric field is formed between the first electrode 201 and the second electrode 202. For example, as the frame driver 300 operates, the frame 100 may rotate. The direction in which the frame 100 rotates may be a rolling direction with reference to the direction in which the frame 100 moves.

The frame 100 may move relative to the substrate SB. For example, the frame 100 may move forward with respect to the substrate SB. For example, the frame 100 may remain stationary and the substrate SB may move, or the substrate SB may remain stationary and the frame 100 may move, or both the frame 100 and the substrate SB may move at a different rate.

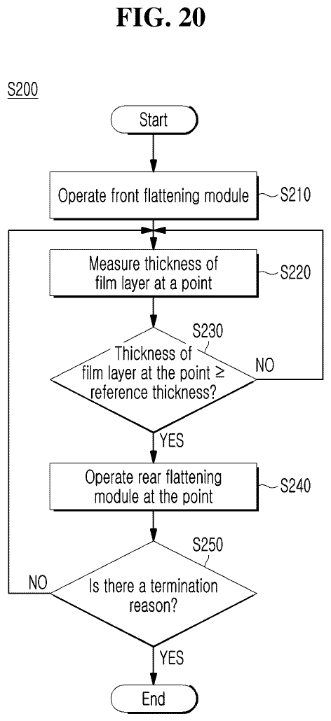

FIG. 20 is a flowchart illustrating a flattening module operation step illustrated in FIG. 19.

The flattening module operation step S200 illustrated in FIG. 20 may represent a method in which the front flattening module 10F, the sensor 62, and the rear flattening module 10R illustrated in FIG. 18 operate.

Referring to FIGS. 1 to 20, the flattening module operation step S200 may include a step S210 of operating the front flattening module 10F. For example, the front flattening module 10F may form an electric flux and may rotate and move.

The flattening module operation step S200 may include a step S220 in which the sensor 62 measures a thickness of the film layer FL at a point of the film layer FL. For example, the controller 63 may acquire information on the thickness of the film layer FL at the point of the film layer FL from the second signal S2 transmitted by the sensor 62.

The flattening module operation step S200 may include a step S230 of determining whether the thickness of the film layer FL at the point of the film layer FL is greater than or equal to a reference thickness. For example, the controller 63 may perform the step S230.

If the thickness of the film layer FL at the point of the film layer FL is determined to be less than the reference thickness, a thickness measurement position of the film layer FL may be changed, and the step S220 of measuring the thickness of the film layer FL may be performed.

The flattening module operation step S200 may include a step S240 of operating the rear flattening module 10R at the point. For example, if the thickness of the film layer FL at the point of the film layer FL is determined to be greater than or equal to the reference thickness, the rear flattening module 10R may operate at the point. Hence, the film layer FL may be effectively flattened.

The flattening module operation step S200 may include a step S250 of determining whether there is a termination reason. In the step S250, the controller 63 may determine whether there is a reason for terminating the flattening module operation step S200. If the controller 63 determines that there is no reason for terminating the flattening module 10, the controller 63 may perform the step S220 of measuring the thickness of the film layer FL at the point.

For example, the reason for terminating the flattening module operation step S200 may be at least one of a case in which the point measured by the sensor 62 is a rear end of the film layer FL, a case in which a failure occurs in the flattening device 1, or a case in which a forced termination command is included in the first signal S1.

For example, the step S250 of determining whether there is the termination reason may be performed between the step S210 of operating the front flattening module and the step S220 of measuring the thickness of the film layer FL at the point.

For another example, the step S250 of determining whether there is the termination reason may be performed between the step S220 of measuring the thickness of the film layer FL at the point of the film layer FL and the step S230 of comparing the thickness of the film layer FL at the point with the reference thickness.

Referring to FIGS. 1 to 20, the flattening module 10 can flatten the film layer FL applied to the substrate SB, and the film layer FL can form a thin film. In this context, the flattening module 10 may be referred to as a “thin film flattening module”, and the flattening device 1 may be referred to as a “thin film flattening device.”

It is noted that the flattening module may be part of an electronic devices used in the production of electronics such as display panels. The electronic device may be a flattening device and may include a flattening nodule, and various other elements such as an electrode power supply, a case, a controller computer, etc.

While various embodiments of the present disclosure have been particularly shown and described with reference to the accompanying drawings, it will be understood by those skilled in the art that various changes in form and details may be made therein without departing from the spirit and scope of the present disclosure.

What is claimed is:

1. A flattening module, comprising:
a frame, including:
a frame body extending from a first end to a second end in a longitudinal direction; and
a mount forming an outer face of the frame body;
a first electrode, including:
a first electrode hub adjacent to the first end of the frame body; and
a plurality of first electrode segments extending from the first electrode hub in the longitudinal direction; and
a second electrode, including:
a second electrode hub adjacent to the second end of the frame body; and
a plurality of second electrode segments extending from the second electrode hub in the longitudinal direction,
wherein first electrode segments of the plurality of first electrode segments and second electrode segments of the plurality of second electrode segments are alternately arranged along a perimeter of the mount and are spaced apart from each other.

2. The flattening module of claim 1, wherein the flattening module is configured to provide an electric potential of the first electrode and an electric potential of the second electrode that are different from each other.

3. The flattening module of claim 1, wherein the first electrode hub and the second electrode hub are disposed on the mount.

4. The flattening module of claim 1, wherein the frame body includes:
a first frame body end face which extends along the longitudinal direction and forms the first end; and
a second frame body end face which extends along the longitudinal direction and forms the second end,
wherein the first electrode hub is disposed on the first frame body end face, and
wherein the second electrode hub is disposed on the second frame body end face.

5. The flattening module of claim 4, wherein the first electrode hub includes:
a first electrode hub body disposed on the first frame body end face; and
a plurality of first electrode hub legs, each of the plurality of first electrode hub legs extending from the first electrode hub body to a corresponding one of the plurality of first electrode segments,
wherein the second electrode hub includes:
a second electrode hub body disposed on the second frame body end face; and
a plurality of second electrode hub legs, each of the plurality of second electrode hub legs extending from the second electrode hub body to a corresponding one of the plurality of second electrode segments.

6. The flattening module of claim 1, wherein the mount has a cylindrical shape.

7. The flattening module of claim 1, wherein the mount has a polygonal pillar shape.

8. The flattening module of claim 7, wherein the mount includes:
a plurality of mounting faces, a corresponding one of the plurality of first electrode segments and the plurality of second electrode segments being mounted on each of the plurality of mounting faces; and
a plurality of mounting edges, each of which forms a boundary between two adjacent mounting faces of the plurality of mounting faces.

9. The flattening module of claim 7, wherein the mount includes:
a plurality of mounting faces, a corresponding one of the plurality of first electrode segments and the plurality of second electrode segments being mounted on each of the plurality of mounting faces; and
a plurality of boundary faces, each of which is disposed between two adjacent mounting faces of the plurality of mounting faces.

10. The flattening module of claim 1, wherein the frame includes:
a plurality of protrusions protruding from the outer face of the frame body; and
a plurality of concave valleys on the outer face of the frame body.

11. The flattening module of claim 10, wherein the protrusions of the plurality of protrusions and the valleys of the plurality of valleys are alternately arranged along the perimeter of the mount,
wherein each of a plurality of mounting faces is formed between two adjacent ones among the plurality of protrusions and the plurality of valleys, and
wherein the plurality of first electrode segments and the plurality of second electrode segments are disposed on a corresponding one of the plurality of mounting faces.

12. The flattening module of claim 1, further comprising:
a frame driver configured to provide a rotational force to the frame.

13. An electronic device, comprising:
a flattening module; and
an electrode power supply configured to provide an electric power to the flattening module,
wherein the flattening module includes:
a frame, including:
a frame body extending from a first end in a longitudinal direction to a second end; and
a mount forming an outer face of the frame body;
a frame driver configured to provide a rotational force to the frame;
a first electrode, including:
a first electrode hub adjacent to the first end of the frame body; and
a plurality of first electrode segments extending from the first electrode hub in the longitudinal direction; and
a second electrode, including:
a second electrode hub adjacent to the second end of the frame body; and
a plurality of second electrode segments extending from the second electrode hub in the longitudinal direction,
wherein first electrode segments of the plurality of first electrode segments and second electrode segments of the plurality of second electrode segments are alternately arranged along a perimeter of the mount and are spaced apart from each other.

14. The electronic device of claim 13, further comprising:
a mover rail system including:
a mover mount on which the flattening module is mounted; and
a mover rail,
wherein the mover mount is movably coupled to the mover rail.

15. The electronic device of claim 13, further comprising:
a sensor configured to measure a thickness of a display module disposed below the flattening module; and
a controller electrically connected to the sensor, the electrode power supply, and the flattening module.

16. The electronic device of claim 15, wherein the flattening module includes a front flattening module and a rear flattening module which are spaced apart from each other and are configured to move in a forward direction,
wherein the sensor is disposed between the front flattening module and the rear flattening module, and
wherein the controller is configured to control the rear flattening module based on information on the thickness of the display module which is acquired from the sensor.

17. A method of forming a thin film, the method comprising:
moving a fluid application unit forward and applying a film layer to an upper face of a substrate; and
moving a flattening module, forming an electric flux above the film layer, forward while the flattening module rotates and flattens the film layer.

18. The method of claim 17, wherein the flattening module includes:
a frame, including:
a frame body extending from a first end in a longitudinal direction to a second end; and
a mount forming an outer face of the frame body;
a first electrode, including:
a first electrode hub adjacent to the first end of the frame body; and
a plurality of first electrode segments extending from the first electrode hub in the longitudinal direction; and
a second electrode, including:
a second electrode hub adjacent to the second end of the frame body; and
a plurality of second electrode segments extending from the second electrode hub in the longitudinal direction,
wherein first electrode segments of the plurality of first electrode segments and second electrode segments of the plurality of second electrode segments are alternately arranged along a perimeter of the mount and are spaced apart from each other.

19. The method of claim 17, wherein an operation of the flattening module includes:
rotating a front flattening module and moving the front flattening module forward while the front flattening module forms an electric flux;
measuring a thickness of the film layer at a point of the film layer by using a sensor;
comparing the measured thickness with a reference thickness by a controller; and
forming the electric flux above the point of the film layer by a rear flattening module disposed behind the front flattening module and moving the rear flattening module forward while the rear flattening module rotates, when the measured thickness is greater than or equal to the reference thickness.

20. The method of claim 19, wherein the sensor changes a measurement position of the film layer and measures a thickness of the film layer, when the measured thickness is less than the reference thickness.
